(19) United States
(12) Patent Application Publication
(10) Pub. No.: US 2007/0108514 A1
(43) Pub. Date: May 17, 2007

(54) Semiconductor device and method of fabricating the same

(76) Inventors: Akira Inoue, Takatsuki-shi (JP); Takeshi Takagi, Kyoto-shi (JP); Haruyuki Sorada, Hirakata-shi (JP)

Correspondence Address: MCDERMOTT WILL & EMERY LLP, 600 13TH STREET, NW, WASHINGTON, DC, 20005-3096, US

(21) Appl. No.: 10/554,860

(22) PCT Filed: Apr. 28, 2004
(86) PCT No.: PCT/JP04/06157

§ 371 Date: Nov. 9, 2006

(30) Foreign Application Priority Data
Apr. 28, 2003 (JP) 2003-124043

(51) Int. Cl. H01L 29/94

(52) U.S. Cl. 257/330

(57) ABSTRACT

A semiconductor device according to the present invention, which comprises a MISFET, has a semiconductor layer (3) having a recessed portion (101) formed in the surface thereof, the recessed portion (101) having an opening the outer circumference of which is closed, a gate insulating film (13) formed so as to cover at least the inner face of the recessed portion (3), a gate electrode (14) filling the recessed portion (101) such that the gate insulating film (13) is interposed between the gate electrode (14) and the inner face of the recessed portion (101), and a pair of source/drains (102), located on both sides of the gate electrode (14) when viewed in plan and formed to a predetermined depth from the surface of the semiconductor layer (3).

### RELATED APPLICATION

This application is the U.S. National Phase under 35 U.S.C. § 371 of International Application No. PCT/JP2004/006157, filed on Apr. 28, 2004, which in turn claims the benefit of Japanese Application No. 2003-124043, filed on Apr. 28, 2003, the disclosure of which Applications are incorporated by reference herein.

### TECHNICAL FIELD

The present invention relates to a semiconductor device, and particularly to a MIS transistor having an elevated source/drain structure, in which a source and a drain are formed at higher positions than a gate insulating film.

### BACKGROUND ART

To date, advancing miniaturization has been the guiding principle to improve the performance of field effect transistors (FETs). For sub-100 nm generation MISFETs (metal-insulator semiconductor FETs), it has been essential that the source/drain high-concentration diffusion layer be made shallow in order to prevent short channel effects and punch-through. Making the source/drain high-concentration diffusion layer shallow causes the portion located below the silicide layer of the source/drain high-concentration diffusion layer to have a reduced thickness, resulting in an increase in the parasitic resistance component and an increase in the junction leakage in the pn junction between the source/drain high-concentration diffusion layer and a body region, which originates from the silicide layer. In order to deal with such a problem, an elevated source/drain structure, in which a portion of each of the source and the drain adjacent to its connection portion to a contact is located outside the silicon substrate, has drawn considerable attention in recent years (see, for example, Satoshi Yamakawa et al., IEEE Electron Device Lett., Vol. 20, No. 7, p. 366, 1999).

FIG. 9 is a cross-sectional view schematically illustrating the construction of a MISFET having such a conventional elevated source/drain structure.

Referring to FIG. 9, in this MISFET, epitaxial Si or polysilicon is selectively grown on a surface of a substrate (SOI substrate) 1 to form protruding portions 18, and by constructing upper portions of silicide layers 11, that is, the adjacent portions to the connection portions to contacts 15 for the source and the drain (hereafter referred to as upper portions of the source and the drain) with these protruding portions 18, the positions of the source and the drain are elevated. Note that reference numeral 2 denotes a SiO₂ box layer, reference numeral 3 denotes a Si body layer, reference numeral 4 denotes an insulator, reference numeral 9 denotes a sidewall, reference numeral 12 denotes an interlayer insulating film, reference numeral 13 denotes a gate insulating film, and reference numeral 14 denotes a gate electrode.

Particularly with a fully depleted device using an SOI substrate, the thickness of the Si body layer for realizing full depletion has tended to be reduced increasingly as the gate is miniaturized further. In sub-100 nm generation devices the thickness of the Si body layer needs to be as thin as about 30 nm. In an SOI device, if the silicide layer reaches the SiO₂ box layer, the contact area between the silicide layer and the source/drain diffusion layer reduces significantly, increasing the resistance. In an attempt to reduce the thickness of the Si body layer in an SOI device as well, it is possible to avoid the problems originating from the silicide layer by adopting the elevated source/drain structure.

In addition, the technique of enhancing the current drive power by using a strained Si layer deposited on a SiGe layer for a channel layer has attracted attention in recent years, which is expected to be brought into practical use (for example, see: Zhi-Yuan Cheng et al., IEEE Electron Device Lett., Vol. 22, No. 7, p. 321, 2001.). With this technique, the strained Si layer on the SiGe layer cannot be deposited thicker than a critical film thickness, so a thin film with a thickness of about 10 to 60 nm is used generally. The SiGe layer, however, is known to have the function to inhibit the formation of cobalt silicide (CoSi₂), which is widely used for the contact portions in semiconductor elements (for example, cf R. A. Donaton et al., Appl. Phys. Lett., Vol. 70, No. 10, p. 1266, 1997), and the thickness reduction in strained Si layer can become a cause of variation in contact resistance. Thus, in the utilization of strained Si device as well, problems associated with the silicide formation can be avoided by adopting the elevated source/drain structure.

Nevertheless, formation of the elevated source/drain structure by selective growth has problems such as follows. (See FIG. 9.)

With reference to FIG. 9, problems involved in a conventional elevated source/drain structure made by selective growth will be discussed. The left half of FIG. 9 illustrates an ideal elevated source/drain structure, while the right half of FIG. 9 illustrates problems involved in an elevated source/drain structure.

<Problem 1> Disorder in impurity profile (indicated by reference numeral 19)

With the elevated source/drain structure, a source/drain diffusion layer 10 is formed by implanting impurity ions into the Si body layer 3, and thereafter, the protruding portions 18, which form the upper portions of the source and the drain, are formed by selective growth; consequently, the impurity profile of the source/drain diffusion layer 10 is disordered because of the heat treatment during the selective growth of the protruding portions 18. When the impurity profile is disordered, variations in the effective gate length and short channel effects occur, causing the threshold voltage to fluctuate. To suppress this, reducing the temperature of the selective growth (generally 700° C. or lower) is necessary. This, however, creates a problem of lower throughput because the growth rate of low-temperature Si growing is slow.

<Problem 2> Polysilicon deposition on sidewall (indicated by reference numeral 20)

With the elevated source/drain structure, the protruding portions 18 are formed by selective growth of epitaxial Si or polysilicon, but in the selective growth of polysilicon, polysilicon may deposit on the sidewall 9 and so forth. The sidewall 9 covers the side faces of the gate electrode 14. The deposited polysilicon can bring about electrical short-circuiting between the gate and the source or between the gate and the drain. In order to prevent this, it is necessary to achieve high selectivity in the selective growth of epitaxial Si or polysilicon. To enhance the selectivity, addition of a hydrogen chloride gas during the crystal growth is known to be effective; however, the use of a chlorine-based gas may risk corrosion of chamber or piping.

<Problem 3> Local impurity profile disorder in a facet portion (indicated by reference numeral 21)

In the selective growth, a facet (crystal face) is formed in the edge portion of a mask pattern aperture for the selective growth. In such a facet portion, the impurity profile tends to be disordered locally because of channeling effects or the like during the impurity ion implantation. The impurity profile fluctuation can bring about variations in contact resistance. The shape of the facet is difficult to control because it depends on the aperture rate of the mask pattern and the material of the mask in addition to the conditions for the crystal growth.

As discussed above, although the elevated source/drain structure has proved to be effective in improving device performance, the selective growth for forming the elevated source/drain structure has not yet been practical because it has many problems.

### DISCLOSURE OF THE INVENTION

It is an object of the present invention to provide a semiconductor device and a method of fabricating the same that are capable of realizing an elevated source/drain structure without using selective growth in forming the source/drain.

In order to accomplish the object, a semiconductor device according to the present invention comprising a MISFET, comprises: a semiconductor layer having a recessed portion formed in a surface thereof, the recessed portion having an opening whose outer circumference is closed; a gate insulating film formed so as to cover at least an inner face of the recessed portion; a gate electrode filling the recessed portion such that the gate insulating film is interposed between the gate electrode and the inner face of the recessed portion; and a pair of source/drains, located on both sides of the gate electrode when viewed in plan and formed to a predetermined depth from the surface of the semiconductor layer. This configuration makes it possible to realize an elevated source/drain structure without using selective growth in forming the source/drain.

The foregoing semiconductor may further comprise: a first sidewall, which has tubular form and is made of an insulator, provided along the opening of the recessed portion so as to protrude from the surface of the semiconductor layer; wherein: the gate insulating film is formed so as to cover an inner circumferential face of the first sidewall and the inner face of the recessed portion; the gate electrode fills an interior of the first sidewall and the recessed portion such that the gate insulating film is interposed between the gate electrode and the inner circumferential face of the first sidewall and the recessed portion; and the pair of source/drains are formed so as to be located on both sides the first sidewall when viewed in plan.

The foregoing semiconductor layer may be made of silicon.

The foregoing semiconductor device may comprise a substrate having the foregoing semiconductor layer.

The foregoing substrate may be an SOI substrate, and the foregoing semiconductor layer may be formed by a Si body layer.

It is preferable that the recessed portion be formed in the Si body layer; that a silicide layer be formed in portion of the source/drain including the surface thereof, and that the following expressions be satisfied:
T1<T2, and
T3<T2,
where T1 is the thickness of the silicide layer, T2 is the thickness of a portion of the Si body layer in which the recessed portion is not formed, and T3 is the thickness of a portion of the Si body layer in which the recessed portion is formed.

The foregoing substrate may have a SiGeC channel layer through which carriers run and a Si cap layer formed on the SiGeC channel layer, and the foregoing semiconductor layer may be formed by the Si cap layer.

It is preferable that: the recessed portion be formed in the Si cap layer; that a silicide layer be formed in portion of the source/drain including the surface thereof, and that the following expressions be satisfied:
T1<T4, and
T5<T4,
where T1 is the thickness of the silicide layer, T4 is the thickness of a portion of the Si cap layer in which the recessed portion is not formed, and T5 is the thickness of a portion of the Si cap layer in which the recessed portion is formed.

The foregoing substrate may have a lattice-relaxed SiGeC layer, and a strained Si channel layer formed on the lattice-relaxed SiGeC layer, and the semiconductor layer may be formed by the strained Si channel layer.

It is preferable that: the recessed portion be formed in the strained Si channel layer; that the silicide layer be formed in portion of the source/drain including the surface thereof, and that the following expressions be satisfied
T1<T6 and
T7<T6,
where T1 is the thickness of the silicide layer, T6 is the thickness of a portion of the strained Si channel layer in which the recessed portion is not formed, and T7 is the thickness of a portion of the strained Si channel layer in which the recessed portion is formed.

The gate insulating film may be formed such that the gate insulating film covers, and is in contact with, the inner circumferential face of the first sidewall and the inner face of the recessed portion.

The recessed portion may have an inner circumferential face and a bottom face, a second sidewall made of an insulator may be formed so as to cover the inner circumferential face of the first sidewall and the inner circumferential face of the recessed portion, and the gate insulating film may be formed so as to cover the bottom face of the recessed portion and so as to cover the inner circumferential face of the recessed portion such that the second sidewall is interposed between the gate insulating film and the inner circumferential face of the recessed portion.

The source/drain may have a silicide layer, and the silicide layer may contain any one of TiSi₂, VSi₂, CrSi₂, ZrSi₂, NbSi₂, MoSi₂, HfSi₂, TaSi₂, WSi₂, NiSi₂, NiSi, CoSi₂, CoSi, Pt₂Si, PtSi, Pd₂Si, and PdSi, or combinations thereof.

The foregoing first sidewall may include a silicon nitride film.

The foregoing gate electrode may be made of any one of the materials selected from Al, Cu, W, Mo, Ti, Ta, WSi, MoSi₂, TiSi₂, TiN, and TaN, or may be formed by stacked layers made of a plurality of materials selected from these materials

The foregoing gate insulating film may be made of any one of the materials selected from SiO₂, ZrO₂, Zr—Si—O, Zr—Si—O—N, HfO₂, Hf—Si—O, Hf—Si—O—N, SiN, TiO₂, La₂O₃, SiON, Al₂O₃, SrTiO₃, BaSrTiO₃, Nd₂O₃, and Ta₂O₅, or may be formed by stacked layers made of a plurality of materials selected from these materials.

A method, according to the present invention, of fabricating a semiconductor device comprising a MISEFT, comprises: (a) forming a dummy gate electrode on a semiconductor substrate; (b) ion-implanting an impurity using the dummy gate electrode as a mask to form an extension diffusion layer in the semiconductor substrate; (c) forming a first sidewall made of an insulator having tubular form so as to surround a side face of the dummy gate electrode; (d) ion-implanting an impurity using the dummy gate electrode and the first sidewall as a mask and thereby forming source/drains in the semiconductor substrate in a self-aligned manner; (e) subsequent to the step (d), forming an interlayer insulating film so as to cover a surface of the semiconductor substrate; (f) selectively removing the dummy gate electrode by dry etching using the interlayer insulating film as a mask; (g) forming a gate recess in the semiconductor substrate that lies below a region from which the dummy gate electrode has been removed; (h) forming a gate insulating film in a recessed form so as to cover an inner circumferential face of the first sidewall and an inner face of the gate recess; and (i) forming a gate electrode in a self-aligned manner so as to fill an interior of the gate insulating film in the recessed form. This configuration makes it possible to realize an elevated source/drain structure without using selective growth in forming the source/drain.

The foregoing step (g) may be a step of, using the interlayer insulating film as a mask, selectively etching the semiconductor substrate lying below a region from which the dummy gate electrode has been removed, by dry etching, to form the gate recess in the semiconductor substrate.

The foregoing step (g) may include the steps of: (m) selectively oxidizing a portion below the region from which the dummy gate electrode has been removed using the interlayer insulating film as a mask; and (n) a step of removing the oxide film that has been selectively oxidized to form the gate recess in the semiconductor substrate.

The foregoing step (h) may include the steps of: (k) forming a second sidewall made of an insulator so as to cover the inner circumferential face of the first sidewall and the inner circumferential face of the gate recess; and (l) forming the gate insulating film in a recessed form so as to cover an inner circumferential face of the second sidewall and a bottom face of the gate recess.

The foregoing and other objects, features, and advantages of the present invention will be made apparent from the following detailed description of preferred embodiments when taken in conjunction with the accompanying drawings.

### BRIEF DESCRIPTION OF THE DRAWINGS

FIG. 1 is a plan view schematically illustrating the structure, viewed in plan, of a semiconductor device according to a first embodiment of the present invention.

FIG. 2 is a cross-sectional view taken along line II-II in FIG. 1, schematically illustrating the structure, viewed in cross-section, of the semiconductor device according to the first embodiment of the present invention.

FIGS. 3(a) through 3(i) are cross-sectional views illustrating, step by step, a first method of fabricating the semiconductor device according to the first embodiment of the present invention.

FIGS. 4(a) through 4(d) are cross-sectional views illustrating, step by step, a second method of fabricating the semiconductor device according to the first embodiment of the present invention.

FIG. 5 is a cross-sectional view schematically illustrating the configuration of a semiconductor device according to a first modified example of the first embodiment of the present invention.

FIG. 6 is a cross-sectional view schematically illustrating the configuration of a semiconductor device according to a second modified example of the first embodiment of the present invention.

FIG. 7 is a cross-sectional view schematically illustrating the configuration of a semiconductor device according to a second embodiment of the present invention.

FIGS. 8(a) through 8(d) are cross-sectional views illustrating, step by step, a method of fabricating the semiconductor device according to the second embodiment of the present invention.

FIG. 9 is a cross-sectional view schematically illustrating the configuration of a conventional MISFET having an elevated source/drain structure.

### BEST MODE FOR CARRYING OUT THE INVENTION

Hereinbelow, embodiments of the present invention are described with reference to the drawings.

### FIRST EMBODIMENT

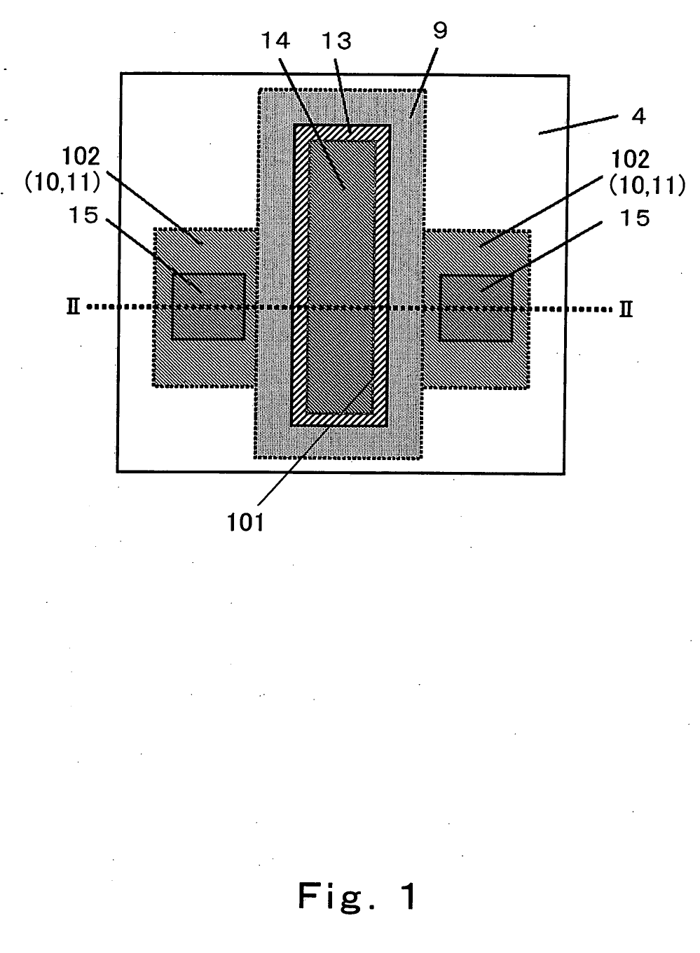

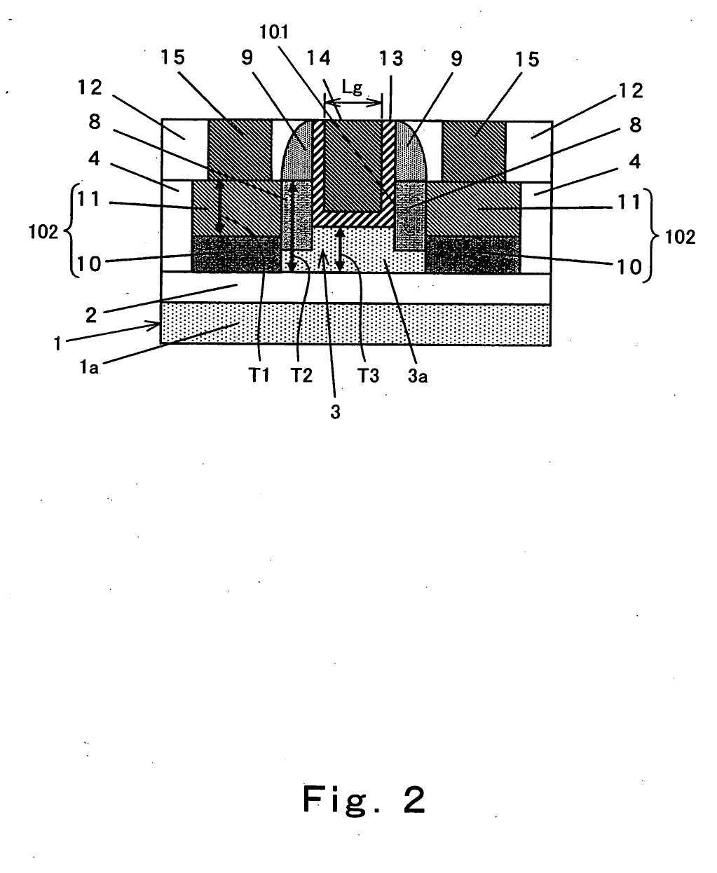

FIG. 1 is a plan view schematically illustrating the structure of a semiconductor device, viewed in plan, according to a first embodiment of the present invention, and. FIG. 2 is a cross-sectional view taken along line II-II in FIG. 1, schematically illustrating the structure of the semiconductor device, viewed in cross-section, according to the first embodiment of the present invention.

Herein, the semiconductor device is a n-MISFET. As a substrate 1, an SOI substrate is used.

Referring to FIGS. 1 and 2, the semiconductor device has a substrate 1. Herein, the substrate 1 is made of an SOI substrate. The SOI substrate 1 is constructed by forming a SiO₂ box layer 2 and a Si body layer 3 on a Si substrate 1a in that order. In the present specification, this unprocessed Si body layer in the SOI substrate 1 is referred to as a “Si body layer,” and is represented by reference numeral 3. Various constituent elements of the semiconductor device are constructed within the Si body layer 3 through processing, and the constituent elements of the semiconductor device are represented by exclusive reference numerals. Particularly a Si body region that is formed so as to remain in the central region of the Si body layer 3 may be confused with the “Si body layer”, so the “Si body region” is termed as such in order to distinguish them clearly, and is denoted by reference numeral 3a. In the Si body layer 3 an insulator 4 for isolating elements is formed to a predetermined depth from the surface (across the entire thickness of the body layer 3 herein), and an active region is formed by a region surrounded by the insulator 4. A rectangular recessed portion (more precisely, a recessed portion in a rectangular parallelepiped shape having an opening the outer circumference of which is closed rectangularly, which is hereinafter referred to as a “gate recess”) 101 is formed in the central portion of the surface of the active region of the Si body layer 3. On the edge portion of the gate recess 101, a first sidewall 9 in rectangular tubular form is formed so as to protrude upward. The first sidewall 9 is made of an insulating film. The inner circumferential face of the first sidewall 9 is formed so as to locate substantially within the same plane as the inner circumferential face of the gate recess 101 (so as not to produce a surface level difference). A gate insulating film 13 is formed so as to cover, and come in contact with, the inner faces (the circumferential faces and the bottom face) of both the gate recess 101 and the first sidewall 9. That is, the gate insulating film 13 is formed into a container-like shape (in a recessed form) in a rectangular tubular form such that its lower end is closed and its upper end is open. A gate electrode 14 is formed so as to fill the interior space of the container-like gate insulating film 13.

The gate electrode 14 has a rectangular shape when viewed in plan, and herein, its shorter side directions are set along the gate length direction. That is, a pair of source/drains 102, 102 are formed in the Si body layer 3 so as to be on both sides of the gate electrode 14 that are along the shorter side directions when viewed in plan and be in contact with the first sidewall 9. The pair of source/drains 102, 102 are formed across the entire thickness of the Si body layer 3. Each source/drain 102 comprises a silicide layer 11 formed to have a thickness T1 and a source/drain diffusion layer 10 formed directly below the silicide layer 11. The silicide layer 11, precisely speaking, protrudes several nanometers from the surface of the Si body layer 3. The amount of the protrusion, however, takes up only a very small proportion with respect to the thickness of the SOI substrate 1, which is 700 μm, so the silicide layer 11 may be regarded as being formed substantially immediately underneath the surface of the SOI substrate 1 and the Si body layer 3. The source/drain diffusion layer 10 is formed by a high-concentration n-type region.

A pair of extension diffusion layers 8, 8 are formed between the gate recess 101 and the pair of source/drains 102, 102 (in the regions underneath the first sidewall 9 that are in contact with the pair of source/drains 102, 102 when viewed in plan). Each extension diffusion layer 8 is formed from the surface of the Si body layer 3 to a position that is lower than the bottom of the gate recess 101. Each extension diffusion layer 8 is formed by a low-concentration n-type region. A Si body region 3a is formed in a portion of the Si body layer 3 that is located below the pair of extension diffusion layers 8, 8 and the gate recess 101. The Si body region 3a is formed by a middle-concentration p-type region.

An interlayer insulating film 12 is formed so as to cover the surface of the substrate 1 in which thus, the gate electrode 14, the gate insulating film 13, the first sidewall 9, and the pair of source/drains 102, 102 are formed.

Contacts 15 piercing through the interlayer insulating film 12 are connected to the pair of source/drains 102, 102. Wiring lines, which are not shown in the drawings, are connected to the upper ends of the contacts 15. Likewise, a contact, which is not shown in the drawings, that pierces through the interlayer insulating film 12 is connected to the gate electrode 14, and a wiring line, which is not shown in the drawings, is connected to the upper end of the contact 15. It should be noted that one of the pair of source/drains 102, 102 serves as a source while the other one serves as a drain during the use of this semiconductor device.

Incidentally, if the silicide layer 11 reaches the SiO₂ box layer 2, the contact area between the silicide layer 11 and the semiconductor regions (the extension diffusion layer 8, the Si body region 3a, and so forth) reduces significantly and therefore the contact resistance between the silicide layer 11 and the semiconductor regions significantly increases. To avoid this problem, it is desirable that in the present embodiment the lower end positions of the source/drain 102, the silicide layer 11, and the gate recess 101 are set so as to satisfy the following conditions.

The thickness of the silicide layer 11 is T1, as mentioned above. The thickness of the source/drain 102 (the distance from the surface of the Si body layer 3 to the lower end of the source/drain 102) is represented by T2, and the thickness of the Si body region 3a that is below the gate recess 101 (the distance from the lower end of the gate recess 101 to the lower end of the source/drain 102) is represented by T3.

In this case, it is desirable that T1, T2, and T3 are set to satisfy the following expressions:
T3<T2, and
T1<T2.

Herein, when a fully depleted SOI device is to be produced, it is desirable that:
T3<Lg/3,
where Lg is the gate length. It should be noted that because FIG. 2 depicts some portions exaggerated as needed, T3 and Lg in FIG. 2 does not appear to satisfy the foregoing relationship. In addition, when the silicide layer 11 is made of Ti silicide, it is desirable that the thickness T1 thereof be set at about 20 to 60 nm, and when the silicide layer 11 is made of Co silicide, it is desirable that the thickness T1 thereof be set at about 10 to 40 nm. In these cases, it is necessary to determine the values of T2 and T3 so as to satisfy the foregoing expressions.

Next, methods of fabricating the semiconductor device will be explained, which are discussed as a first fabrication method and a second fabrication method below.

{First Fabrication Method}

Firstly, a first fabrication method is explained.

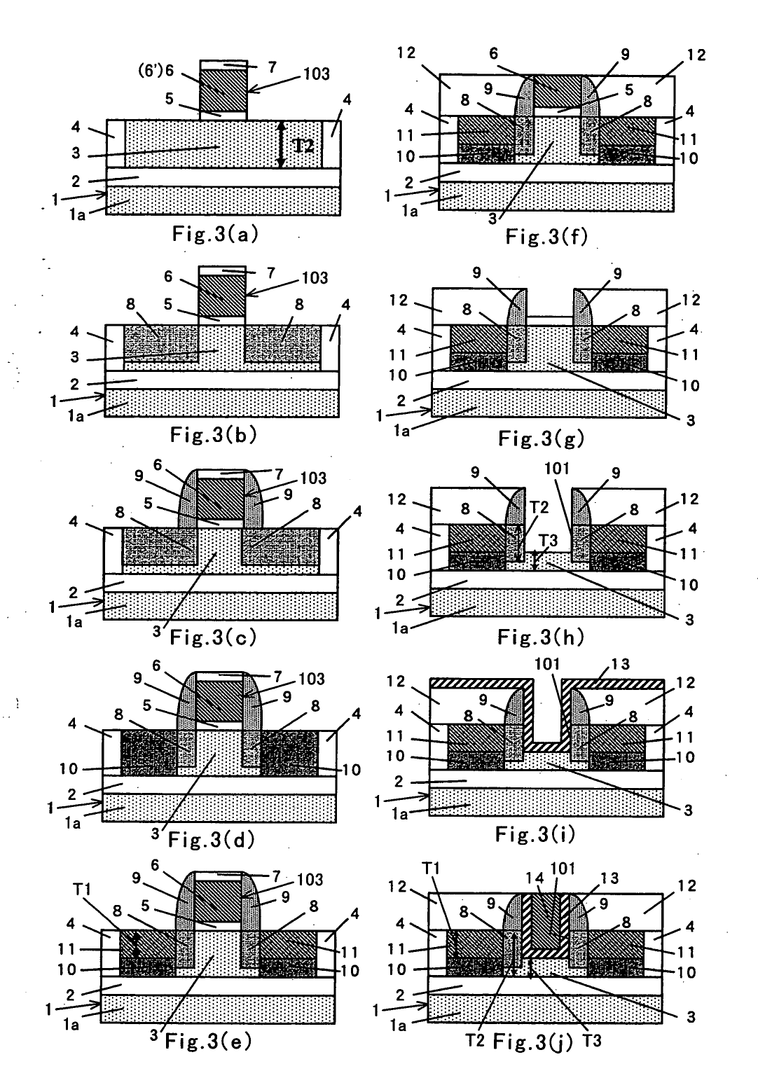

FIGS. 3(a) through 3(i) are cross-sectional views illustrating, step by step, the first method of fabricating the semiconductor device of the present embodiment.

[Step of Forming a Dummy Gate (FIG. 3(a))]

Referring to FIG. 3(a), first, the SOI substrate 1 is prepared. The SOI substrate 1 comprises the Si substrate 1a, the SiO₂ box layer 2 having a thickness of about 100 nm, which is formed on the Si substrate 1a, and the Si body layer 3 having a thickness T2, which is formed on the SiO₂ box layer 2. Next, an element isolation is formed as the insulator 4 in the Si body layer 3 of the SOI substrate 1. For this element isolation, shallow trench isolation (STI) or deep trench isolation (DTI) is used. Next, boron is ion-implanted into the active region surrounded by the insulator 4 for adjusting a threshold value. The ion implantation is carried out two times, and the implantation conditions are 60 keV and 13×10¹³ cm⁻³, and 10 keV and 2×10¹² cm⁻³. Thereby, the active region is turned into a p-type conductive region. Next, an about 10 nm thick dummy insulating film 5 made of SiO₂ is formed over the entire surface of the SOI substrate 1. This dummy insulating film 5 is utilized as an etch stop layer in the dry etching of a dummy gate. A CVD method or thermal oxidation is used for forming the dummy insulating film 5. Next, an about 200 nm thick dummy gate film 6′ made of polysilicon is formed on the dummy insulating film 5. The dummy gate film 6′ is used as a dummy for forming a metal gate in a self-aligned manner. Next, a dummy gate passivation film 7 made of a SiO₂ or SiN film is formed on the dummy gate film 6′ to a thickness of about 18 nm. The dummy gate passivation film 7 is for protecting the polysilicon dummy gate so as not to be turned into a silicide when forming a silicide layer in the step of FIG. 3(e).

Next, using a resist mask formed by lithography, formation of a dummy gate 6 is carried out by means of dry etching. Herein, the dummy gate passivation film 7 may be used as a hard mask. Thereby, a rectangular parallelepiped body 103 made of the dummy insulating film 5, the dummy gate 6, and the dummy gate passivation film 7 is formed.

[Step of Forming Extension (FIG. 3(b))]

Next, referring to FIG. 3(b), arsenic is ion-implanted into predetermined regions of the Si body layer 3 that are located on both sides of the dummy gate 6 when viewed in plan to form the n-type extension diffusion layer 8. The implantation conditions are 8 keV and 5×10¹² cm⁻³.

[Step of Forming a First Sidewall (FIG. 3(c))]

Next, referring to FIG. 3(c), the first sidewall 9 made of a SiO₂ or SiN film is formed. For the formation of the first sidewall 9, a CVD method and an entire surface etch-back by dry etching are used. The first sidewall 9 is formed so as to surround the side wall of the rectangular parallelepiped body 103 and is consequently formed into a rectangular tubular form. The first sidewall 9 may have a stacked structure of SiO₂ and SiN films. Constructing the first sidewall by a SiN film has an advantage that the gate length does not vary in the wet process using a hydrofluoric acid.

[Step of Implantation for Source/Drain (FIG. 3(d))]

Next, referring to FIG. 3(d), arsenic is ion-implanted into predetermined regions of the Si body layer 3 that are located on both sides of the first sidewall 9 when viewed in plan, to form the source/drain diffusion layer 10. The implantation conditions are 40 keV and 4×10¹³ cm⁻³. Next, activation annealing is performed. For the annealing, RTA is used. The process temperature is about 850° C. to 1100° C., and the process duration is about 1 to 60 sec.

[Step of Forming Silicide (FIG. 3(e))]

Next, referring to FIG. 3(e), the silicide layer 11 is formed in predetermined regions of the source/drain diffusion layer 10. The silicide layer 11 is made of any one of TiSi₂, VSi₂, CrSi₂, ZrSi₂, NbSi₂, MoSi₂, HfSi₂, TaSi₂, WSi₂, NiSi₂, NiSi, CoSi₂, CoSi, Pt₂Si, PtSi, Pd₂Si, and PdSi, or combinations thereof.

Here, it is possible to widen the area in which the silicide layer 11 is in contact with the semiconductor (that is, the area in which the silicide layer 11 is in contact with the source/drain diffusion layer 10 and with the extension diffusion layer 8) by setting the thickness T1 of the silicide layer 11 so as to satisfy the expression:
T1<T2,
and thus the effect of preventing the contact resistance from increasing can be obtained.
[Step of Forming an Interlayer Insulating Film (FIG. 3(f))]

Next, referring to FIG. 3(f), the interlayer insulating film 12 is deposited over the entire surface of the SOI substrate 1 that has been subjected to the foregoing steps. The interlayer insulating film 12 is formed by a SiO₂ film, a TEOS film, a SiN film, or the like, and is deposited using a CVD method. Next, surface planarization is carried out using a chemical mechanical polishing (CMP) technique. At this time, the polishing is performed until the dummy gate passivation film 7 is removed.

[Step of Removing the Dummy Gate (FIG. 3(g))]

Next, referring to FIG. 3(g), the dummy gate 6, which has been exposed, is removed by a dry etching process. For the dry etching gas, it is desirable to use chlorine, bromine, or a mixed gas thereof When using these gases, it is possible to selectively remove only the dummy gate 6 using the interlayer insulating film 12 as a mask. Moreover, the first sidewall 9 is not etched.

[Step of Forming a Gate Recess (FIG. 3(h))]

Next, referring to FIG. 3(h), the dummy insulating film 5 is removed by dry etching. Thereby, a rectangular parallelepiped-shaped space is formed in the interior of the first sidewall 9 that has a rectangular tube form. For the dry etching gas, it is desirable to use CF₄, CHF₃, or a mixed gas thereof. It is also possible to add an argon gas or a hydrogen gas thereto.

Next, the gate recess 101 having a rectangular parallelepiped shape is formed in the Si body layer 3 by dry-etching the Si body layer 3 that is located below the interior space of the first sidewall 9. For the dry etching gas, it is desirable to use chlorine, bromine, or a mixed gas thereof. When using these gases, it is possible to selectively etch only the Si body layer 3 using the interlayer insulating film 12 as a mask. Moreover, there is an advantage that the first sidewall 9 is not etched.

Herein, when the thickness of the portion of the Si body layer 3 that is located below the gate recess 101 is T3, as mentioned previously, it is desirable to satisfy the expression:
T3<T2.
By selectively dry etching only the portion of the the Si body layer 3 that is located below the interior space of the first sidewall 9 in this way, it becomes possible to realize an elevated source/drain in a self-aligned manner without using a selective growth method.

It is also possible to carry out the steps of FIGS. 3(g) and 3(h) by a single dry etching step.

[Step of Forming Gate Insulating Film (FIG. 3(i))]

Next, referring to FIG. 3(i), the gate insulating film 13 is deposited over the entire surface of the SOI substrate 1 that has been subjected to the foregoing steps. Thereby, the inner circumferential face of the first sidewall 9, and the inner circumferential face and the bottom face of the gate recess 101 are covered with the gate insulating film 13 while making contact with the gate insulating film 13. The subsequent process may use a low temperature process, the process temperature of which is at most about 400° C., and therefore it is also possible to use a high-k dielectric film of HfO₂, ZrO₂, Ta₂O₅, or the like for the gate insulating film 13. Specifically, the gate insulating film 13 may be made of any one of the materials from SiO₂, ZrO₂, Zr—Si—O, Zr—Si—O—N, HfO₂, Hf—Si—O, Hf—Si—O—N, SiN, TiO₂, La₂O₃, SiON, Al₂O₃, SrTiO₃, BaSrTiO₃, Nd₂O₃, and Ta₂O₅, or may be constructed by stacking layers made of a plurality of materials selected from these materials.

[Step of Forming Gate Electrode Forming Step (FIG. 30))]

Next, referring to FIG. 3(j), a gate film made of polysilicon or a metal such as Al, which later forms the gate electrode 14, is formed on the gate insulating film 13. Thereby, the interior space of the first sidewall 9 and the gate recess 101 are filled with the gate film so that the gate insulating film 13 is interposed therebetween. Since the present process is a low temperature process, there is an advantage that it is possible to use a metal as the material for the gate electrode 14. In the case of using a metal, it is more preferable to deposit a metal film that later forms the gate electrode 14 after depositing a barrier metal such as a TiN layer. Specifically, in the case of forming the gate electrode 14 by a metal, the gate electrode 14 may be made of any one of the materials from Al, Cu, W, Mo, Ti, Ta, WSi, MoSi₂, TiSi₂, TiN, and TaN, or may be constructed by stacking layers made of a plurality of materials selected from these materials.

Next, planarization is performed by CMP. Thereby, the gate electrode 14 that fills the interior space of the first sidewall 9 and the gate recess 101 is formed so that the gate insulating film 13 is interposed therebetween. In addition, the Si body region 3a made of a p-type conductive region is formed so as to be located below the extension diffusion layer 8 and the gate recess 101.

Thereafter, as shown in FIG. 2, the contacts 15 are formed so as to pierce through the interlayer insulating film 12 and come in contact with the silicide layer 11. Also, a contact (not shown in FIG. 2) is formed so as to pierce through the interlayer insulating film 12 and come in contact with the gate electrode 14. Wiring lines (not shown in FIG. 2) are formed so as to be connected to the upper ends of these contacts. Thus, the semiconductor device is completed.

The present process can form the gate recess, which is formed so as to be filled with the gate electrode 14 therein, in the Si body layer 3 in a self-aligned manner; therefore, it is possible to realize a similar structure to the elevated source/drain structure by a simplified process without using a selective growth method. As a consequence, all the problems associated with the selective growth can be resolved because the selective growth is not used. Moreover, the present process can utilize a low temperature process with a process temperature of at most about 400° C. for the steps that follow the activation annealing of the source/drain diffusion layer 10 (after the step of FIG. 3(d)) and therefore has an additional advantage that the problem of disorder in the impurity profile that arises in the conventional fabrication method can be avoided. Furthermore, because the present process is a low temperature process, it is possible to adopt a high-k gate electrode, a metal gate electrode, or the like.

Additionally, in the present embodiment, the gate electrode 14 is formed in the gate recess 101 of the Si body layer 3, and the first sidewall 9 is formed on the surface of the Si body layer 3; therefore, the thickness (T2) of the semiconductor layer below the first sidewall 9 becomes thicker than the thickness (T3) of the semiconductor layer below the gate electrode 14. For this reason, the resistance of the extension portion can be lowered in comparison with the conventional example, in which the thickness of the semiconductor layer below the gate electrode 14 is equal to the thickness of the semiconductor layer below the sidewall.

{Second Fabrication Method}

Next, a second fabrication method is explained.

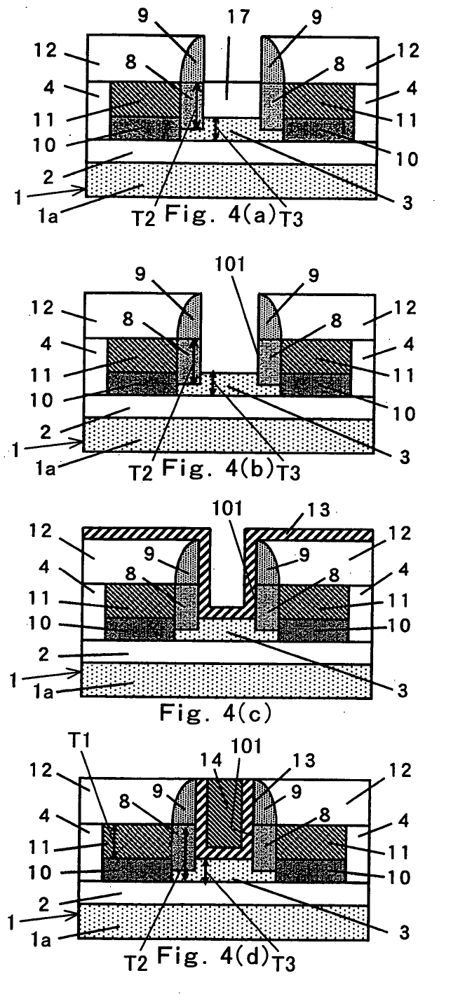

FIGS. 4(a) through 4(d) are cross-sectional views illustrating, step by step, the second method of fabricating the semiconductor device of the present embodiment.

The second fabrication method differs from the first fabrication method in the method of forming the gate recess 101, but is similar to the first fabrication method in other respects. Accordingly, since the fabrication steps from the step of forming the dummy gate (FIG. 3(a)) to the step of removing the dummy gate (FIG. 3(g)) are in common with the first fabrication method, the description thereof is omitted here and only the fabrication steps that follow the step of forming the gate recess will be explained.

[Step 1 of Turning the Portion Below the Gate into a Thin Film (FIG. 4(a))]

Referring to FIG. 4(a), the dummy gate insulating film 5 is removed by dry etching or wet etching using a hydrofluoric acid, and thereafter, thermal oxidation is performed for the Si body layer 3 that has been exposed in the interior space of the first sidewall 9. At this time, because a Si portion that is exposed on the surface of the SOI substrate 1 is only the Si body layer 3 exposed in the interior space of the first sidewall 9, it is possible to oxidize only this region selectively. Thereby, a selectively oxidized region 17 is formed in the upper portion of the Si body layer 3. At this time, the selective oxidation is controlled so that the thickness of the portion of the Si body layer 3 that is located below the selectively oxidized region 17 results in T3 in the first fabrication method.

[Step 2 of Turning the Portion Below the Gate into a Thin Film (FIG. 4(b))]

Next, referring to FIG. 4(b), the selectively oxidized region 17 is removed by wet etching using a hydrofluoric acid. Thereby, the gate recess 101 is formed in the Si body layer 3. Also, the film thickness of the Si body layer 3 from which the selectively oxidized region 17 has been removed becomes T3 as mentioned previously. Thus, by employing thermal oxidation and wet etching, only the Si body layer 3 that is located below the interior space of the first sidewall 9 can be selectively etched away. In contrast to the first fabrication method, in which the gate recess 101 is formed by dry etching, the second fabrication method is characterized in that the gate recess 101 is formed by selective oxidation. The selective oxidation process has the advantages that it is possible to avoid etching damage and moreover the controllability in the film thickness direction is high. Thus, the second fabrication method makes it possible to realize an elevated source/drain structure in a self-aligned manner without using selective growth while benefiting from such advantages.

The step of forming a gate insulating film (FIG. 4(c)) and the step of forming a gate electrode (FIG. 4(d)) are the same as those in the first fabrication method and therefore the description thereof is omitted.

It should be noted that the fabrication steps that follow the selective oxidation of the step of forming the gate recess 1 (FIG. 4(a)) are low-temperature processes, the process temperature of which is at most about 400° C. as in the first fabrication method, and therefore, it is possible to adopt a high-k gate electrode, a metal gate electrode, or the like.

It should be noted that although the semiconductor device is formed by a n-MISFET in the foregoing configuration, it is also possible to form this by a p-MISFET. This can be achieved by changing the type of impurity. Specifically, in the step of ion-implanting boron, a n-type dopant such as arsenic, phosphorus, or the like may be used in place of boron. On the other hand, in the step of ion-implanting arsenic or phosphorus, a p-type dopant such as boron may be used in place of arsenic or phosphorus.

In addition, although the SOI substrate is used as the substrate 1 in the foregoing configuration, it is also possible to employ an ordinary Si bulk substrate, in a case of which the above-described fabrication method can of course be applied in the same manner as in the case of the SOI substrate.

Furthermore, it will be apparent that it is possible to form the semiconductor device of the present embodiment by a hetero-MISFET in which the channel is made of a SiGeC layer, or a strained Si MISFET in which the channel is made of a strained Si layer on a lattice-relaxed SiGeC layer, and that the above-described fabrication method can be applied to fabricate these devices.

Next, examples in which the semiconductor device is formed by a hetero MISFET or a strained Si MISFET will be specifically described as a first modified example and a second modified example of the present embodiment.

### FIRST MODIFIED EXAMPLE

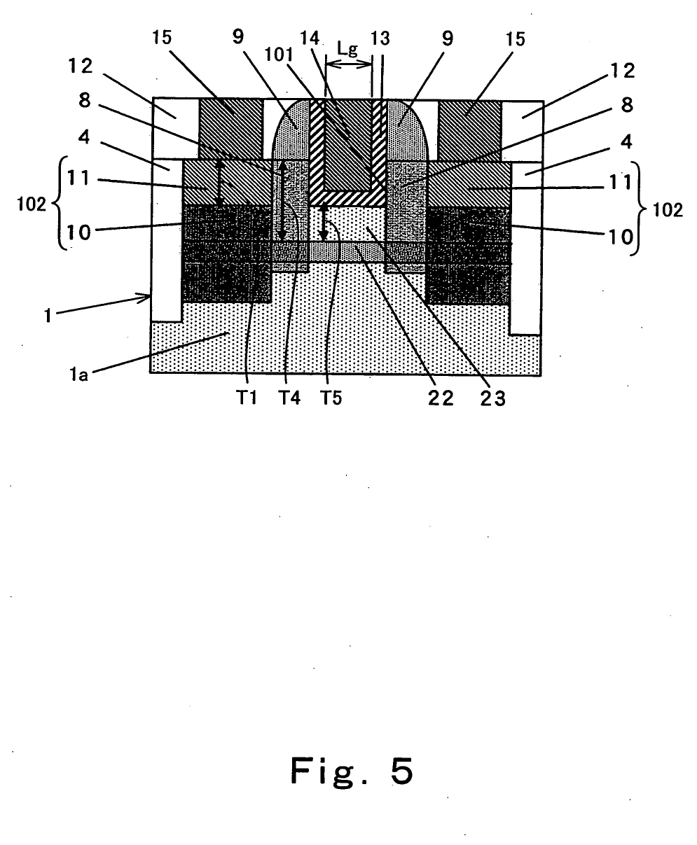

FIG. 5 is a cross-sectional view schematically illustrating a semiconductor device of a first modified example according to the present embodiment.

As illustrated in FIG. 5, the semiconductor device is formed by a hetero MISFET in the present modified example.

The hetero MISFET of the present modified example utilizes, as the substrate 1, a substrate in which a SiGeC channel layer 22 and a Si cap layer 23 having a thickness of about about 5 nm to 20 nm are formed successively on a Si substrate 1a using a UHV-CVD (Ultra High Vacuum Chemical Vapor Deposition) method. Then, an insulator 4 is formed so as to reach the Si substrate 1a, and an active region is formed of the Si substrate 1a, the SiGeC channel layer 22, and the Si cap layer 23 that are surrounded by the insulator 4. In the substrate 1, the gate recess 101 is formed in the Si cap layer 23 because the Si cap layer 23 is the uppermost layer. As shown in FIG. 5, when the thickness of the silicide layer 11 is represented by T1, the initial thickness of the Si cap layer 23 is represented by T4, and the thickness of the portion of the Si cap layer 23 that is located below the gate recess 101 is represented by T5, it is possible to suppress variations in the contact resistance by controlling the thicknesses so as to satisfy the following expressions:
T1<T4, and
T5<T4,
because the SiGeC channel layer 22 is thereby not turned into a silicide. In addition, in order to prevent the parasitic channel produced at the interface between the Si cap layer 23 and the gate insulating film 15, it is preferable that T5 is set within a thin range of from about 1 nm to 10 nm.

### SECOND MODIFIED EXAMPLE

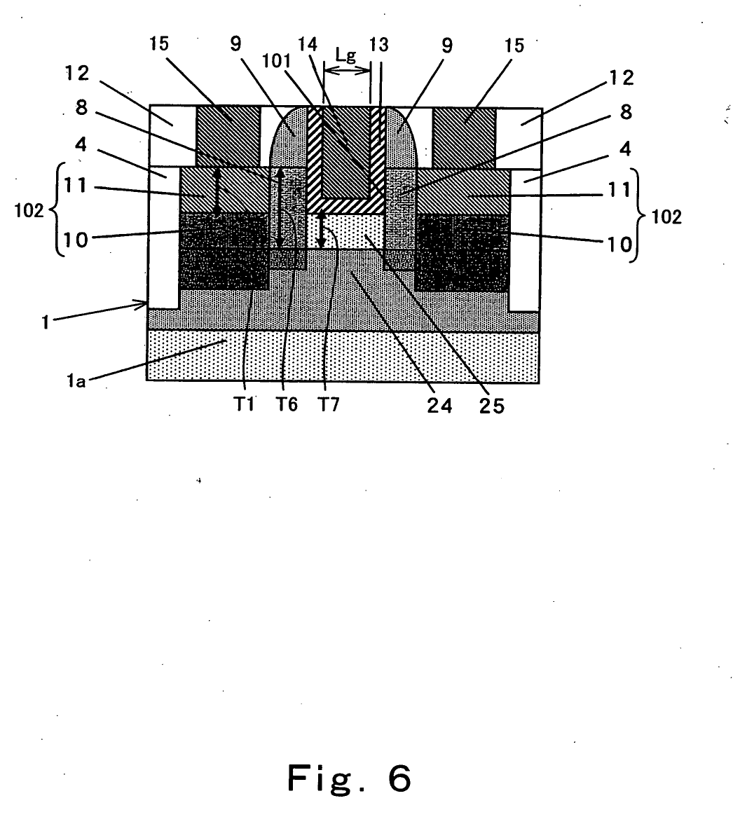

FIG. 6 is a cross-sectional view schematically illustrating the configuration of a semiconductor device of a second modified example according to the present embodiment.

As illustrated in FIG. 6, the semiconductor device is formed by a strained Si MISFET in the present modified example.

The strained Si MISFET of the present modified example utilizes, as the substrate 1, a substrate in which a relaxed SiGeC layer 24 and a strained Si channel layer 25 having a thickness of about 1 μm to 4 μm are formed successively on a Si substrate 1a using a UHV-CVD method. Then, an insulator 4 is formed in the strained Si channel layer 25, and an active region is formed of a region of the strained Si channel layer 25 surrounded by the insulator 4. In the substrate 1, the gate recess 101 is formed in the strained Si channel layer 25 because the strained Si channel layer 25 is the uppermost layer. As shown in FIG. 6, when the film thickness of the silicide layer 11 is represented by T1, the initial thickness of the strained Si channel layer 25 is represented by T6, and the thickness of the portion of the strained Si channel layer 25 that is located below the gate recess 101 is represented by T7, it is possible to suppress variations in the contact resistance by controlling the thicknesses so as to satisfy the following expressions:
T1<T6, and
T7<T6,
because the relaxed SiGeC layer 24 is thereby not turned into a silicide. In order to prevent the strained Si layer 25 from undergoing lattice relaxation, it is preferable that T6 be set within the range of from about 10 nm to 60 nm.

### SECOND EMBODIMENT

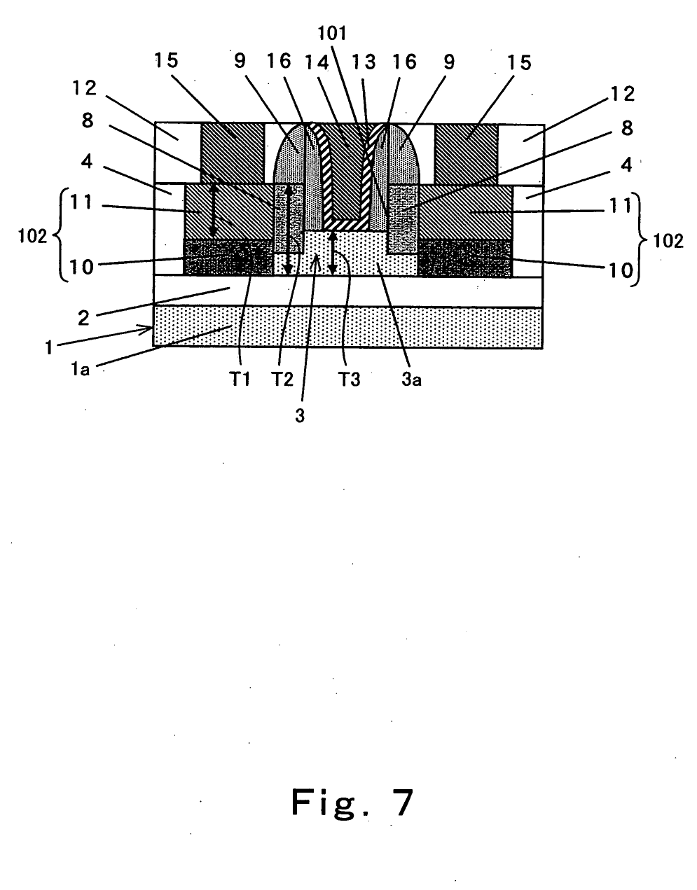

FIG. 7 is a cross-sectional view schematically illustrating the construction of a semiconductor device according to a second embodiment of the present invention. In FIG. 7, the same reference numerals as used in FIG. 1 represent the same or like parts.

As illustrated in FIG. 7, in the present embodiment, a second sidewall 16 made of an insulating film is formed so as to cover, and be in contact with, the inner circumferential face of the first sidewall 9 and the inner circumferential face of the gate recess 101. A gate insulating film 13 is formed so as to cover, and be in contact with, the inner circumferential face of the second sidewall 16 and the bottom face of the gate recess 101. In other words, the gate insulating film 13 is formed so as to cover the inner circumferential face of the first sidewall 9 and the inner circumferential face of the gate recess 101 with the second sidewall 16 interposed therebetween. A gate electrode 14 is formed so as to fill the interior of the container-like gate insulating film 13. In other respects, the second embodiment is similar to the first embodiment.

Since in the present embodiment the second sidewall 16 is formed in this manner, the present embodiment has two advantages as follows. The first advantage is that it is possible to reduce the fringe capacitance between the gate and the source and between the gate and the drain. This enables a high-speed operation. The second advantage is that the gate length can be determined by the second sidewall 16. Furthermore, in addition to the fact that the gate length below the limit of lithography is possible to fabricate, an extremely ideal gate electrode 14 with very small gate length and low gate resistance and low fringe capacitance can be realized because the cross-sectional structure of the gate results in a mushroom structure.

Next, a method of fabricating the semiconductor device constructed in the above-described manner will be explained.

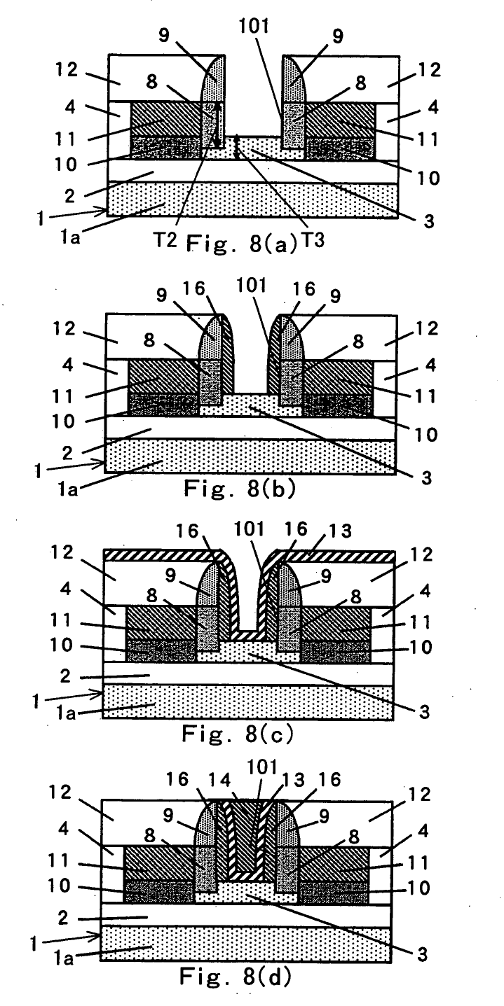

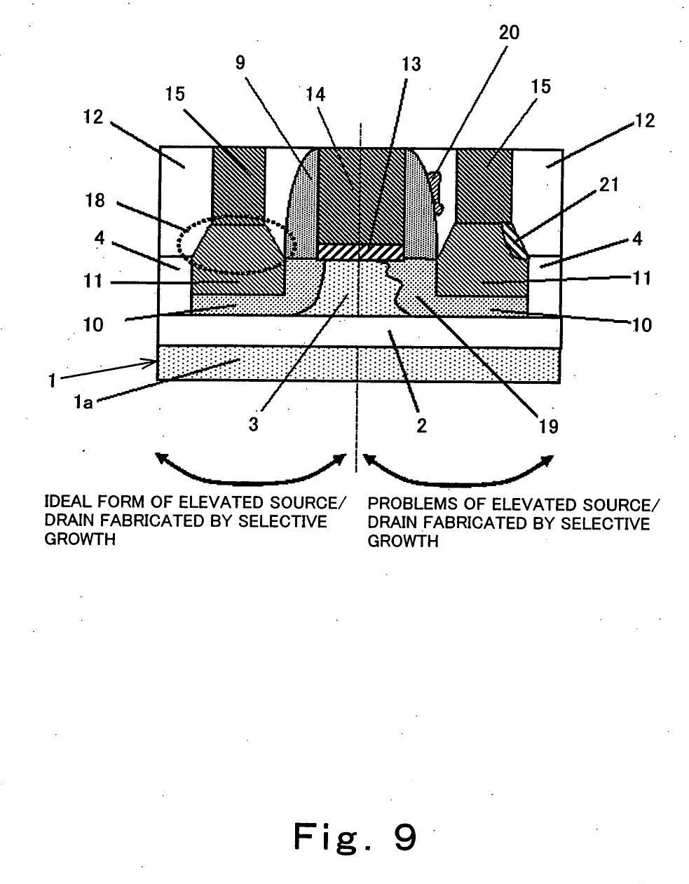

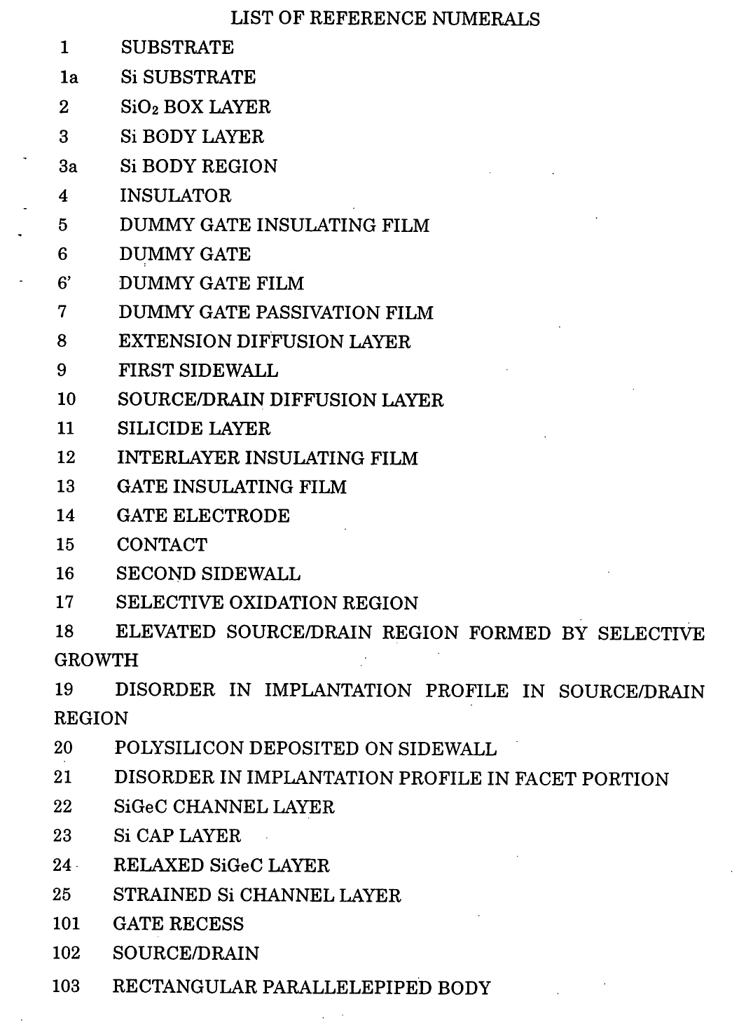

FIGS. 8(a) through 8(d) are cross-sectional views illustrating, step by step, the method of fabricating the semiconductor device according to the present embodiment. In FIGS. 8(a) through 8(d), the same reference numerals as used in FIGS. 3(a) through 3(j) represent the same or like parts.

An important point in the fabrication method in the present embodiment is the method of forming the second sidewall 16. The steps that precede the step of forming the second sidewall 16, up to the step of forming the gate recess, are identical to the first fabrication method in the first embodiment (see FIGS. 3(a) through 3(h)). Accordingly, the explanation thereof is omitted here, and the steps that follow the step of forming the second sidewall will be explained.

[Step of Forming a Second Sidewall (FIG. 8(a))]

In FIG. 8(a), first, a second sidewall film made of a SiO₂ or SiN film is deposited on the surface of a SO substrate 1 that has been subjected to the preceding steps, by a CVD method, and thereafter, an entire surface etch-back is performed by dry etching. Thereby, the second sidewall 16 having a rectangular tubular form is formed on the inner circumferential face of the rectangular parallelepiped-shaped space formed by the interior space of the first sidewall 9 and the gate recess 101. Since the thickness of the second sidewall 16 can be controlled by the initially deposited film thickness of the second sidewall film, it is possible to achieve a gate length that is below the processing limit by lithography. In addition, the formation of the second sidewall 16 has the advantage that it is possible to reduce the gate fringe capacitance and to achieve a high-speed operation. The second sidewall 16 may be formed by a stack structure of a SiO₂ film and a SiN film. When the second sidewall 16 is formed by a SiN film, there is an advantage that the gate length does not change in the wet process using a hydrofluoric acid.

[Step of Forming a Gate Insulating Film (FIG. 8(b))]

Next, in FIG. 8(b), the gate insulating film 13 is deposited over the entire surface of the SO substrate 1 that has been subjected to the foregoing steps. Since the subsequent process is a low temperature process the process temperature of which is at most about 400° C., it is also possible to use a high-k dielectric film of HfO₂, ZrO₂, Ta₂O₅, or the like for the gate insulating film 13.

[Step of Forming a Gate Electrode (FIGS. 8(c) and 8(d))]

Next, in FIG. 8(c), a gate film made of polysilicon, or a metal such as Al, Cu, W, Mo, Ti, or Ta, which later becomes the gate electrode 14, is formed on the gate insulating film 13. Thus, the space formed by the second sidewall 16 and the bottom face of the gate recess 101 is filled with the gate film with the gate insulating film 13 interposed therebetween. Since the present process is a low temperature process, there is an advantage that it is possible to use a metal as the material for the gate electrode 14. In the case of using a metal, it is more preferable to deposit a metal film that later forms the gate electrode 14 after depositing a barrier metal such as a TiN layer.

Next, in FIG. 8(d), planarization is performed by CMP. Thus, a gate electrode 14 is formed to be filled in the space formed by the second sidewall 16 and the bottom face of the gate recess 101 with the gate insulating film 13 interposed therebetween. Thereafter, similar steps to those in the first fabrication method are performed, so that the semiconductor device of the present embodiment is completed.

It should be noted that it is of course possible to use the first fabrication method in the embodiment in the present embodiment, in place of the second fabrication method.

As has been explained thus far, the present embodiment achieves such advantageous effects as realization of a gate length that is below the processing limit by lithography, reduction in gate fringe capacitance, and moreover attaining a gate structure that is a mushroom structure.

It should be noted that in the present embodiment as well, a Si bulk substrate may be used in place of the SOI substrate. Moreover, the present embodiment may be modified in similar manners to those in the first and the second modified examples of the first embodiment.

In the first embodiment and the second embodiment, the layer that has been described as the “SiGeC layer” may be substituted by either one of a SiGe layer, which does not contain C, or a SiC layer, which does not contain Ge.

From the foregoing description, numerous improvements and other embodiments of the present invention will be readily apparent to those skilled in the art. Accordingly, the foregoing description is to be construed only as illustrative examples and as being presented for the purpose of suggesting the best mode for carrying out the invention to those skilled in the art. Various changes and modifications can be made in specific structures and/or functions substantially without departing from the scope and sprit of the invention.

### INDUSTRIAL APPLICABILITY

The semiconductor device according to the present invention is useful as a MISFET or the like having an elevated source/drain structure.

The method of fabricating a semiconductor device according to the present invention is useful as a method of fabricating a MISFET or the like having an elevated source/drain structure.

1. A semiconductor device comprising a MISFET, comprising:
a Ge-containing semiconductor layer made of SiGe or SiGeC;
a Si semiconductor layer made of silicon which is formed on the Ge-containing semiconductor layer and has a recessed portion formed in a surface thereof, the recessed portion having an opening whose outer circumference is closed;
a gate insulating film formed so as to cover at least an inner face of the recessed portion;
a gate electrode filling the recessed portion such that the gate insulating film is interposed between the gate electrode and the inner face of the recessed portion; and
a pair of source/drains located on both sides of the gate electrode when viewed in plan and formed to a predetermined depth from the surface of the Si semiconductor layer.

2. The semiconductor device comprising a MISEFT according to claim 1, further comprising:
a first sidewall, which has tubular form and is made of an insulator, provided along the opening of the recessed portion so as to protrude from the surface of the Si semiconductor layer;
wherein:
the gate insulating film is formed so as to cover an inner circumferential face of the first sidewall and the inner face of the recessed portion;
the gate electrode fills an interior of the first sidewall and the recessed portion such that the gate insulating film is interposed between the gate electrode and the inner circumferential face of the first sidewall and the recessed portion; and
the pair of source/drains are formed so as to be located on both sides the first sidewall when viewed in plan.

3. (canceled)

4. The semiconductor device comprising a MISEFT according to claim 1, comprising a substrate having the Si semiconductor layer and the Ge-containing semiconductor layer.

5-6. (canceled)

7. The semiconductor device comprising a MISEFT according to claim 4, wherein the substrate has a channel layer made of SiGe or SiGeC through which carriers run and a Si cap layer formed on the channel layer, the Si semiconductor layer is formed by the Si cap layer, and the Ge-containing semiconductor layer is formed by the channel layer.

8. The semiconductor device comprising a MISEFT according to claim 7, wherein the recessed portion is formed in the Si cap layer; a silicide layer is formed in portion of the source/drain including the surface thereof; and the following expressions are satisfied:
T1<T4 and
T5<T4,
where T1 is the thickness of the silicide layer, T4 is the thickness of a portion of the Si cap layer in which the recessed portion is not formed, and T5 is the thickness of a portion of the Si cap layer in which the recessed portion is formed.

9. The semiconductor device comprising a MISEFT according to claim 4, wherein the substrate has a lattice-relaxed SiGeC layer and a strained Si channel layer formed on the lattice-relaxed SiGeC layer, the Si semiconductor layer is formed by the strained Si channel layer, and the Ge-containing semiconductor layer is formed by the lattice-relaxed SiGeC layer.

10. The semiconductor device comprising a MISEFT according to claim 9, wherein the recessed portion is formed in the strained Si channel layer; the silicide layer is formed in a portion of the source/drain including the surface thereof; and the following expressions are satisfied:
T1<T6 and
T7<T6,
where T1 is the thickness of the silicide layer, T6 is the thickness of a portion of the strained Si channel layer in which the recessed portion is not formed, and T7 is the thickness of a portion of the strained Si channel layer in which the recessed portion is formed.

11. The semiconductor device comprising a MISEFT according to claim 2, wherein the gate insulating film is formed such that the gate insulating film covers, and is in contact with, the inner circumferential face of the first sidewall and the inner face of the recessed portion.

12. The semiconductor device comprising a MISEFT according to claim 2, wherein the recessed portion has an inner circumferential face and a bottom face, a second sidewall made of an insulator is formed so as to cover the inner circumferential face of the first sidewall and the inner circumferential face of the recessed portion, and the gate insulating film is formed so as to cover the bottom face of the recessed portion and so as to cover the inner circumferential face of the recessed portion such that the second sidewall is interposed between the gate insulating film and the inner circumferential face of the recessed portion.

13. The semiconductor device comprising a MISEFT according to claim 1, wherein the source/drain has a silicide layer, and the silicide layer contains any one of TiSi₂, VSi₂, CrSi₂, ZrSi₂, NbSi₂, MoSi₂, HfSi₂, TaSi₂, WSi₂, NiSi₂, NiSi, CoSi₂, CoSi, Pt₂Si, PtSi, Pd₂Si, and PdSi, or combinations thereof.

14. The semiconductor device comprising a MISEFT according to claim 2, wherein the first sidewall includes a silicon nitride film.

15. The semiconductor device comprising a MISEFT according to claim 1, wherein the gate electrode is made of any one of the materials selected from Al, Cu, W, Mo, Ti, Ta, WSi, MoSi₂, TiSi₂, TiN, and TaN, or formed by stacked layers made of a plurality of materials selected from the materials.

16. The semiconductor device comprising a MISEFT according to claim 1, wherein the gate insulating film is made of any one of the materials selected from SiO₂, Zro₂, Zr—Si—O, Zr—Si—O—N, HfO₂, Hf—Si—O, Hf—Si—O—N, SiN, TiO₂, La₂O₃, SiON, Al₂O₃, SrTiO₃, BaSrTiO₃, Nd₂O₃, and Ta₂O₅, or formed by stacked layers made of a plurality of materials selected from the materials.

17. A method of fabricating a semiconductor device comprising a MISEFT, comprising:
(a) forming a dummy gate electrode on a semiconductor substrate which is comprised of a Si semiconductor layer made of silicon and a Ge-containing semiconductor layer made of SiGe or SiGeC which is located under the Si semiconductor layer, the Si semiconductor layer being an upper surface layer of the substrate;
(b) ion-implanting an impurity using the dummy gate electrode as a mask to form an extension diffusion layer in the semiconductor substrate;
(c) forming a first sidewall made of an insulator having tubular form so as to surround a side face of the dummy gate electrode;
(d) ion-implanting an impurity using the dummy gate electrode and the first sidewall as a mask and thereby forming source/drains in the semiconductor substrate in a self-aligned manner;
(e) subsequent to the step (d), forming an interlayer insulating film so as to cover a surface of the semiconductor substrate;
(f) selectively removing the dummy gate electrode by dry etching using the interlayer insulating film as a mask;
(g) forming a gate recess in the Si semiconductor layer of the semiconductor substrate that lies below a region from which the dummy gate electrode has been removed;
(h) forming a gate insulating film in a recessed form so as to cover an inner circumferential face of the first sidewall and an inner face of the gate recess; and
(i) forming a gate electrode in a self-aligned manner so as to fill an interior of the gate insulating film in the recessed form.

18. The method of fabricating a semiconductor device comprising a MISEFT according to claim 17, wherein the step (g) is a step of, using the interlayer insulating film as a mask, selectively etching the Si semiconductor layer of the semiconductor substrate lying below the region from which the dummy gate electrode has been removed, by dry etching, to form the gate recess in the semiconductor substrate.

19. The method of fabricating a semiconductor device comprising a MISEFT according to claim 18, wherein the step (h) includes the steps of:
(k) forming a second sidewall made of an insulator so as to cover the inner circumferential face of the first sidewall and the inner circumferential face of the gate recess; and
(l) forming the gate insulating film in a recessed form so as to cover an inner circumferential face of the second sidewall and a bottom face of the gate recess.

20. The method of fabricating a semiconductor device comprising a MISEFT according to claim 17, wherein the step (g) includes the steps of:
(m) selectively oxidizing a portion below the region from which the dummy gate electrode has been removed using the interlayer insulating film as a mask; and
(n) a step of removing the oxide film that has been selectively oxidized to form the gate recess in the Si semiconductor layer of the semiconductor substrate.

21. The method of fabricating a semiconductor device comprising a MISEFT according to claim 20, wherein the step (h) includes the steps of:
(k) forming a second sidewall made of an insulator so as to cover the inner circumferential face of the first sidewall and the inner circumferential face of the gate recess; and
(l) forming the gate insulating film in a recessed form so as to cover an inner circumferential face of the second sidewall and a bottom face of the gate recess.
